(19) United States
(12) Patent Application Publication
(10) Pub. No.: US 2013/0328220 A1
(43) Pub. Date: Dec. 12, 2013

(54) INTEGRATED CIRCUIT PACKAGING SYSTEM WITH FILM ASSIST AND METHOD OF MANUFACTURE THEREOF

(71) Applicants: KyungHoon Lee, Icheon (KR); JoungIn Yang, Seoul (KR); SangMi Park, Pucheon-Si (KR); YiSu Park, Icheon-si (KR); DaeSik Choi, Seoul (KR)

(72) Inventors: KyungHoon Lee, Icheon (KR); JoungIn Yang, Seoul (KR); SangMi Park, Pucheon-Si (KR); YiSu Park, Icheon-si (KR); DaeSik Choi, Seoul (KR)

(21) Appl. No.: 13/494,721

(22) Filed: Jun. 12, 2012

(51) Int. Cl. H01L 23/28; H01L 21/56

(52) U.S. Cl. 257/787; 438/127; 257/E21.502; 257/E23.116

(57) ABSTRACT

A method of manufacture of an integrated circuit packaging system includes: providing a substrate; forming an integrated circuit device having a shaped side; mounting the integrated circuit device on the substrate; forming an encapsulation on the substrate and the integrate circuit device with the shaped side partially exposed from the encapsulation.

### TECHNICAL FIELD

The present invention relates generally to an integrated circuit packaging system, and more particularly to a system with film assist.

### BACKGROUND ART

The integrated circuit package is the building block used in a high performance electronic system to provide applications for usage in products such as automotive vehicles, pocket personal computers, cell phone, intelligent portable military devices, aeronautical spacecraft payloads, and a vast line of other similar products that require small compact electronics supporting many complex functions.

A small product, such as a cell phone, can contain many integrated circuit packages, each having different sizes and shapes. Each of the integrated circuit packages within the cell phone can contain large amounts of complex circuitry. The circuitry within each of the integrated circuit packages work and communicate with other circuitry of other integrated circuit packages using electrical connections.

Products must compete in world markets and attract many consumers or buyers in order to be successful. It is very important for products to continue to improve in features, performance, and reliability while reducing product costs, product size, and to be available quickly for purchase by the consumers or buyers.

The amount of circuitry and the amount of electrical connections inside a product are key to improving the features, performance, and reliability of any product. Furthermore, the ways the circuitry and electrical connections are implemented can determine the packaging size, packaging methods, and the individual packaging designs. Attempts have failed to provide a complete solution addressing simplified manufacturing processing, smaller dimensions, lower costs due to design flexibility, increased functionality, leveragability, and increased IO connectivity capabilities.

Thus, a need still remains for an integrated circuit system improved yield, thermal cooling, low profile, and improved reliability. In view of the ever-increasing commercial competitive pressures, along with growing consumer expectations and the diminishing opportunities for meaningful product differentiation in the marketplace, it is increasingly critical that answers be found to these problems. In view of the ever-increasing commercial competitive pressures, along with growing consumer expectations and the diminishing opportunities for meaningful product differentiation in the marketplace, it is critical that answers be found for these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides a method of manufacture of an integrated circuit packaging system, including: providing a substrate; forming an integrated circuit device having a shaped side; mounting the integrated circuit device on the substrate; forming an encapsulation on the substrate and the integrate circuit device with the shaped side partially exposed from the encapsulation.

The present invention provides an integrated circuit packaging system, including: a substrate; an integrated circuit device mounted on the substrate, the integrated circuit device includes a shaped side; and an encapsulation formed on the substrate and the integrate circuit device with the shaped surface partially exposed from the encapsulation.

Certain embodiments of the invention have other steps or elements in addition to or in place of those mentioned above. The steps or elements will become apparent to those skilled in the art from a reading of the following detailed description when taken with reference to the accompanying drawings.

### BRIEF DESCRIPTION OF THE DRAWINGS

FIG. 1 is a top view of the integrated circuit packaging system.

FIG. 2 is a cross-sectional view of the integrated circuit packaging system taken along line 2-2 of FIG. 1 in a first embodiment of the present invention.

FIG. 3 is a detailed view of a partial cross-sectional view of the structure in FIG. 2.

FIG. 4 is a cross-sectional view of the integrated circuit packaging system taken along line 2-2 of FIG. 1 in a second embodiment of the present invention.

FIG. 5 is a detailed view of a partial cross-sectional view of the structure in FIG. 4.

FIG. 6 is a partial cross-sectional view of the integrated circuit packaging system 100 of FIG. 2 in a device-attachment phase of manufacture.

FIG. 7 is the structure of FIG. 6 in a film-assist molding phase.

FIG. 8 is detailed partial view of the structure of FIG. 7.

FIG. 9 is a partial cross-sectional view of the integrated circuit packaging system 100 of FIG. 4 in a device-attachment phase of manufacture.

FIG. 10 is the structure of FIG. 9 in a film-assist molding phase.

FIG. 11 is detailed partial view of the structure of FIG. 10.

FIG. 12 is a partial cross-sectional view of the integrated circuit packaging system of FIG. 4 in a wafer-mount phase of manufacture.

FIG. 13 is the structure of FIG. 12 in a destructible removal process phase of manufacture.

FIG. 14 is the structure of FIG. 13 in a cutting phase of manufacture.

FIG. 15 is the structure of FIG. 14 in a tape-removal phase.

FIG. 16 is the structure of FIG. 15 in a singulation phase.

FIG. 17 is a flow chart of a method of manufacture of the integrated circuit packaging system in a further embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown exaggerated in the drawing FIGs. Similarly, although the views in the drawings for ease of description generally show similar orientations, this depiction in the FIGs. is arbitrary for the most part. Generally, the invention can be operated in any orientation.

The same numbers are used in all the drawing FIGs. to relate to the same elements. The embodiments have been numbered first embodiment, second embodiment, etc. as a matter of descriptive convenience and are not intended to have any other significance or provide limitations for the present invention.

The term “processing” as used herein includes deposition of material or photoresist, patterning, exposure, development, etching, cleaning, and/or removal of the material or photoresist as required in forming a described structure. The term “active side” refers to a side of a die, a module, a package, or an electronic structure having active circuitry fabricated thereon or having elements for connection to the active circuitry within the die, the module, the package, or the electronic structure.

For expository purposes, the term “horizontal” as used herein is defined as a plane parallel to the active surface of the integrated circuit, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures. The term “on” is defined as meaning there is direct contact between elements or components with no intervening material.

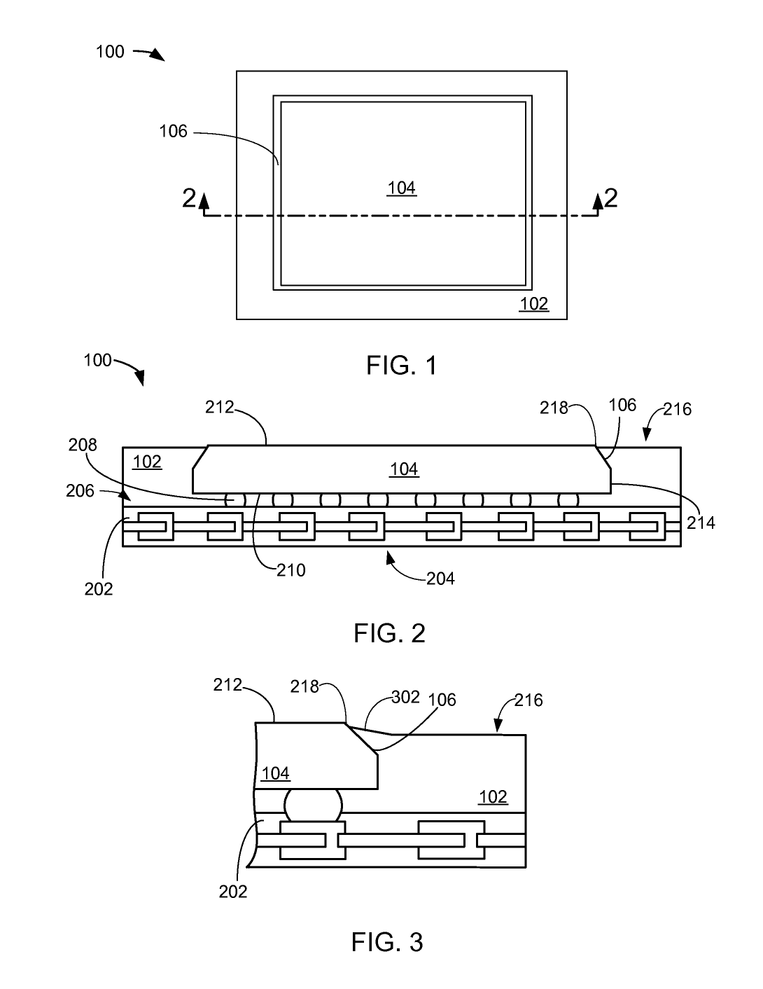

Referring now to FIG. 1, therein is shown a top view of an integrated circuit packaging system 100. The integrated circuit packaging system 100 is shown having an encapsulation 102 and an integrated circuit device 104.

The encapsulation 102 provides mechanical protection, environmental protection, and a hermetic seal for the integrated circuit packaging system 100. The encapsulation 102 can be made from an epoxy molding compound (EMC), film assisted molding, polymide compound, or a wire-in-film (WIF), as examples.

The integrated circuit device 104 is defined as a semiconductor device having one or more integrated transistors for implementing active circuitry. For example, the integrated circuit device 104 can include interconnects, passive devices, or a combination thereof. For example, a flip-chip or a wafer scale chip can be representative of the integrated circuit device 104. The integrated circuit device 104 is exposed from the encapsulation 102.

The integrated circuit device 104 can have grind marks, swirls, small indentions, micro recesses characteristic, or a combination thereof characteristic of a destructible removal process. The destructible removal process can include mechanical grinding, sawing, and cutting.

The integrated circuit device 104 includes a shaped side 106 along a periphery of the exposed surface of the integrated circuit device 104. The shaped side 106 can include different configurations for a surface of the shaped side 106. The shaped side 106 will be explained in further detail below in FIG. 2.

Referring now to FIG. 2, therein is shown a cross-sectional view of the integrated circuit packaging system 100 taken along line 2-2 of FIG. 1 in a first embodiment of the present invention. The integrated circuit packaging system 100 is shown having a substrate 202, the encapsulation 102, and the integrated circuit device 104.

The substrate 202 can provide support and connectivity for components and devices. The substrate 202 can include conductive layers and conductive traces embedded therein. The substrate 202 can include a component side 204 for mounting components, devices, and packages. The substrate 202 can also include a system side 206, which is a side opposite to the component side 204, for connecting to a next system level (not shown).

The integrated circuit device 104 can be attached or mounted to the component side 204 of the substrate 202 by a device interconnect 208. The device interconnect 208 provides an electrical connection and can include a solder ball, a bond wire, solder, or a solder pillar as examples. The device interconnect 208 provides electrical connectivity between the integrated circuit device 104 and the substrate 202.

The integrated circuit device 104 is shown in a flip chip interconnection method although the integrated circuit device 104 can use other configurations for attachment to the substrate 202. For example, the integrated circuit device 104 can be attached to the substrate 202 through a wire-bonding attachment method.

The integrated circuit device 104 can include an interconnect side 210 for attaching the device interconnect 208. The interconnect side 210 can include contacts, fabricated thereon, and directly attached to the device interconnect 208. The integrated circuit device 104 can also include a device top side 212 which is a side opposite the interconnect side 210. The device top side 212 is exposed from and above the encapsulation 102.

The shaped side 106 extends from the device top side 212 and borders the perimeter of the device top side 212. The shaped side 106 can be oblique to the device top side 212. For illustrative purposes, the shaped side 106 is shown having a profile shape of a sloped flat surface. It is understood that the shaped side 106 can have different profile shapes. For example, the shaped side 106 can have a profile shape of a concave surface, a step or multiple steps, a convex surface, a curved sectioned surface, an angled flat sectioned surface, or a surface formed having any combination of surfaces thereof.

The shaped side 106 can have removal marks, uneven surfaces, micro recesses characteristic, or a combination thereof characteristic of a destructible removal process. The destructible removal process can include mechanical sawing, cutting, and laser ablation.

The integrated circuit device 104 can include a non-horizontal side 214 extending from the shaped side 106 to the interconnect side 210. The non-horizontal side 214 can be perpendicular to the substrate 202 or the non-horizontal side 214 can have a concave or a convex shape. An intersection of the non-horizontal side 214 and the shaped side 106 can be formed having a shape and a surface of a sharp corner. The intersection of the non-horizontal side 214 and the shaped side 106 can also have a shape and a surface of a curved corner.

The non-horizontal side 214 can have removal marks, uneven surfaces, micro recesses characteristic, or a combination thereof characteristic of a destructible removal process. The destructible removal process can include mechanical sawing, cutting, and laser ablation. The non-horizontal side 214 can have a rounded surface, a curved surface, or a straight surface. An intersection of the non-horizontal side 214 and the substrate 202 can be straight, curved, or rounded.

The encapsulation 102 covers the substrate 202, the device interconnect 208, and partially covers the integrated circuit device 104. The encapsulation 102 can partially cover the shaped side 106. The encapsulation 102 includes an encapsulation top side 216 facing away from the substrate 202 and below the device top side 212.

The device top side 212 is exposed from the encapsulation 102. The shaped side 106 includes an exposed portion 218 at the intersection of the shaped side 106 and the encapsulation 102. The exposed portion 218 and the device top side 212 can protrude above the encapsulation 102.

It has been discovered that the shaped side 106 with the exposed portion 218 prevents mold bleed onto the device top side 212. For example, it has been unexpectedly found that the shaped side 106 functions as a dam to reduce the epoxy molding compound transfer velocity at the edges of device top side 212 of the integrated circuit device 104. Reliability of the integrated circuit device 104 is increases because mold bleed is prevented from the device top side 212.

It has also been discovered that the present invention provides a consistent surface for mounting components on the device top side 212 because of the prevention of the mold bleed. The shaped side 106 prevents mold bleed onto the device top side 212 reducing manufacturing time and process steps because the mold bleed does not need subsequent removal.

It has also been discovered that the encapsulation 102 partially covering the shaped side 106 and below the device top side 212 provides a mold locking feature for the integrated circuit device 104 that prevents pull out of the integrated circuit device 104 from the encapsulation 102. The encapsulation 102 partially covering the shaped side 106 increases adhesion strength because the shaped side 106 is embedded and anchored within the encapsulation 102.

It has also been discovered that present invention provides for the device top side 212 to be can exposed and above the encapsulation 102 because the shaped side 106 embedded in the encapsulation 102 prevents pull out.

It has also been discovered that the shaped side 106, the intersection of the shaped side 106 and the non-horizontal side 214, the non-horizontal side 214, and the intersection of the non-horizontal side 214 and the substrate 202 can be curved or rounded to provide increased surface area for a stronger mold lock. The curved or rounded surfaces provided increased area for mold to adhere thereon. A curved surface at the intersection of the non-horizontal side 214 and the substrate provides a mold lock between the encapsulation 102 and the integrated circuit device 104 to prevent pullout.

Further, it has been unexpectedly found that the shaped side 106 reduces stress during a singulation process of the integrated circuit device 104. The forming of the shaped side 106 facilitates singulation because less material must be cut through during singulation of a wafer to a die.

Referring now to FIG. 3, therein is shown a detailed view of a partial cross-sectional view of the structure in FIG. 2. The detailed view depicts the substrate 202, the integrated circuit device 104, and the encapsulation 102. The encapsulation top side 216 is below the device top side 212 and the exposed portion 218 of the shaped side 106. The encapsulation top side 216 can be parallel to the substrate 202.

The encapsulation 102 includes a raised portion 302. The raised portion 302 is between the exposed portion 218 and a portion of the encapsulation top side 216 parallel to the substrate 202. The raised portion 302 of the encapsulation 102 is below the exposed portion 218 of the shaped side 106 and above a portion of the shaped side 106 covered by the encapsulation 102. The raised portion 302 provides mold locking and prevents pull out of the integrated circuit device 104 from the encapsulation 102.

The raised portion 302 can have a configuration or shape characteristic of being formed by a film assist molding process on the shaped side 106. The shape of the raised portion 302 is determined by the compression of film below the device top side 212 and onto the shaped side 106. The raised portion 302 can include sloped profile, a concave surface, a convex surface, a curved sectioned surface, an angled flat sectioned surface, or a surface formed having any combination of surfaces thereof.

It has also been discovered that the raised portion 302 of the encapsulation 102 partially covering the shaped side 106 and below the device top side 212 provides a mold locking feature for the integrated circuit device 104 that prevents pull out of the integrated circuit device 104 from the encapsulation 102. The raised portion 302 partially covering the shaped side 106 increases adhesion strength because the shaped side 106 is embedded and anchored within the encapsulation 102.

It has also been discovered that present invention provides for the device top side 212 to be can exposed and above the encapsulation 102 because the shaped side 106 embedded in the encapsulation 102 prevents pull out.

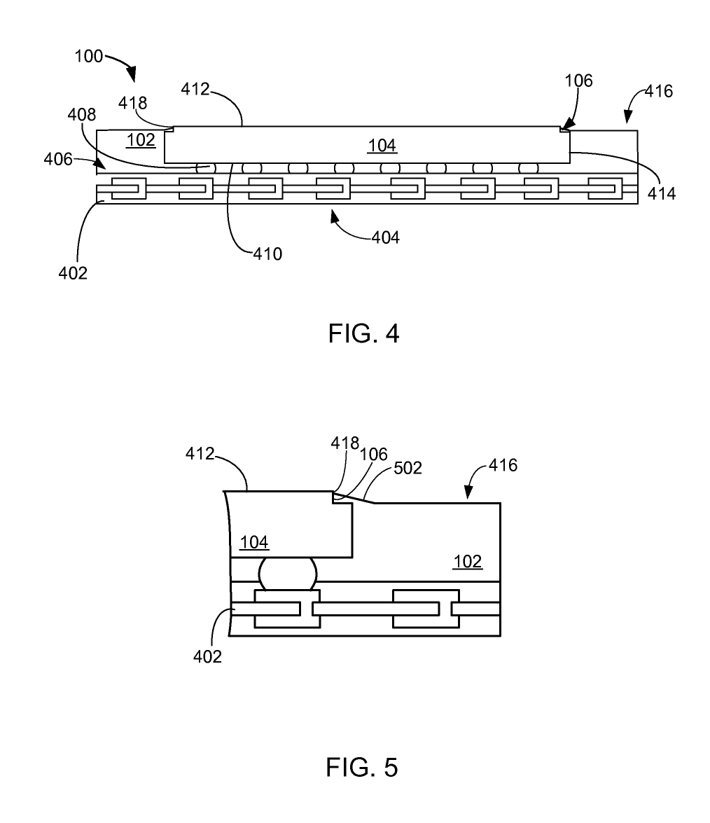

Referring now to FIG. 4, therein is shown a cross-sectional view of the integrated circuit packaging system 100 taken along line 2-2 of FIG. 1 in a second embodiment of the present invention. The integrated circuit packaging system 100 is shown having a substrate 402, the encapsulation 102, and the integrated circuit device 104.

The substrate 402 can provide support and connectivity for components and devices. The substrate 402 can include conductive layers and conductive traces embedded therein. The substrate 402 can include a component side 404 for mounting components, devices, and packages. The substrate 402 can also include a system side 406, which is a side opposite to the component side 404, for connecting to a next system level (not shown).

The integrated circuit device 104 can be attached or mounted to the component side 404 of the substrate 402 by a device interconnect 408. The device interconnect 408 provides an electrical connection and can include a solder ball, a bond wire, solder, or a solder pillar as examples. The device interconnect 408 provides electrical connectivity between the integrated circuit device 104 and the substrate 402.

The integrated circuit device 104 is shown in a flip chip interconnection method although the integrated circuit device 104 can use other configurations for attachment to the substrate 402. For example, the integrated circuit device 104 can be attached to the substrate 402 through a wire-bonding attachment method.

The integrated circuit device 104 can include an interconnect side 410 for attaching the device interconnect 408. The interconnect side 410 can include contacts, fabricated thereon, and directly attached to the device interconnect 408. The integrated circuit device 104 can also include a device top side 412 which is a side opposite the interconnect side 410. The device top side 412 is exposed from and above the encapsulation 102.

The shaped side 106 extends from the device top side 412 and borders the perimeter of the device top side 412. The shaped side 106 can be oblique to the device top side 412. For illustrative purposes, the shaped side 106 is shown having a profile shape of a step. It is understood that the shaped side 106 can have different profile shapes. For example, the shaped side 106 can have a profile shape of a straight slope, multiple steps, a concave surface, a convex surface, a curved sectioned surface, an angled flat sectioned surface, or a surface formed having any combination of surfaces thereof.

The shaped side 106 can have removal marks, uneven surfaces, micro recesses characteristic, or a combination thereof characteristic of a destructible removal process. The destructible removal process can include mechanical sawing, cutting, and laser ablation.

The integrated circuit device 104 can include a non-horizontal side 414 extending from the shaped side 106 to the interconnect side 410. The non-horizontal side 414 can be perpendicular to the substrate 402 or the non-horizontal side 414 can have a concave or a convex shape. An intersection of the non-horizontal side 414 and the shaped side 106 can be formed having a shape and a surface of a sharp corner. The intersection of the non-horizontal side 414 and the shaped side 106 can also have a shape and a surface of a curved corner.

The non-horizontal side 414 can have removal marks, uneven surfaces, micro recesses characteristic, or a combination thereof characteristic of a destructible removal process. The destructible removal process can include mechanical sawing, cutting, and laser ablation. The non-horizontal side 414 can have a rounded surface, a curved surface, or a straight surface. An intersection of the non-horizontal side 214 and the substrate 202 can be straight, curved, or rounded.

The encapsulation 102 covers the substrate 402, the device interconnect 408, and partially covers the integrated circuit device 104. The encapsulation 102 can partially cover the shaped side 106. The encapsulation 102 includes an encapsulation top side 416 facing away from the substrate 402 and below the device top side 412.

The device top side 412 is exposed from the encapsulation 102. The shaped side 106 includes an exposed portion 418 at the intersection of the shaped side 106 and the encapsulation 102. The exposed portion 418 and the device top side 412 can protrude above the encapsulation 102.

It has been discovered that the shaped side 106 with the exposed portion 418 prevents mold bleed onto the device top side 412. For example, it has been unexpectedly found that the shaped side 106 functions as a dam to reduce the epoxy molding compound transfer velocity at the edges of the device top side 412 of the integrated circuit device 104. Reliability of the integrated circuit device 104 is increases because mold bleed is prevented from the device top side 412.

It has also been discovered that the present invention provides a consistent surface for mounting components on the device top side 412 because of the prevention of the mold bleed. The shaped side 106 prevents mold bleed onto the device top side 412 reducing manufacturing time and process steps because the mold bleed does not need subsequent removal.

It has also been discovered that the encapsulation 102 partially covering the shaped side 106 and below the device top side 412 provides a mold locking feature for the integrated circuit device 104 that prevents pull out of the integrated circuit device 104 from the encapsulation 102. The encapsulation 102 partially covering the shaped side 106 increases adhesion strength because the shaped side 106 is embedded and anchored within the encapsulation 102.

It has also been discovered that present invention provides for the device top side 412 to be can exposed and above the encapsulation 102 because the shaped side 106 embedded in the encapsulation 102 prevents pull out.

It has also been discovered that the shaped side 106, the intersection of the shaped side 106 and the non-horizontal side 414, the non-horizontal side 414, and the intersection of the non-horizontal side 414 and the substrate 402 can be curved or rounded to provide increased surface area for a stronger mold lock. The curved or rounded surfaces provided increased area for mold to adhere thereon. A curved surface at the intersection of the non-horizontal side 414 and the substrate provides a mold lock between the encapsulation 102 and the integrated circuit device 104 to prevent pullout.

Further, it has been unexpectedly found that the shaped side 106 reduces stress during a singulation process of the integrated circuit device 104. The forming of the shaped side 106 facilitates singulation because less material must be cut through during singulation of a wafer to a die.

Referring now to FIG. 5, therein is shown a detailed view of a partial cross-sectional view of the structure in FIG. 4. The detailed view depicts the substrate 402, the integrated circuit device 104, and the encapsulation 102. The encapsulation top side 416 is below the device top side 412 and the exposed portion 418 of the shaped side 106. The encapsulation top side 416 can be parallel to the substrate 402.

The encapsulation 102 includes a raised portion 502. The raised portion 502 is between the exposed portion 418 and a portion of the encapsulation top side 416 parallel to the substrate 402. The raised portion 502 of the encapsulation 102 is below the exposed portion 418 of the shaped side 106 and above a portion of the shaped side 106 covered by the encapsulation 102. The raised portion 502 provides mold locking and prevents pull out of the integrated circuit device 104 from the encapsulation 102.

The raised portion 502 can have a configuration or shape characteristic of being formed by a film assist molding process on the shaped side 106. The shape of the raised portion 502 is determined by the compression of film below the device top side 412 and onto the shaped side 106. The raised portion 502 can include sloped profile, a concave surface, a convex surface, a curved sectioned surface, an angled flat sectioned surface, or a surface formed having any combination of surfaces thereof.

It has also been discovered that the raised portion 502 of the encapsulation 102 partially covering the shaped side 106 and below the device top side 412 provides a mold locking feature for the integrated circuit device 104 that prevents pull out of the integrated circuit device 104 from the encapsulation 102. The raised portion 502 partially covering the shaped side 106 increases adhesion strength because the shaped side 106 is embedded and anchored within the encapsulation 102.

It has also been discovered that present invention provides for the device top side 412 to be can exposed and above the encapsulation 102 because the shaped side 106 embedded in the encapsulation 102 prevents pull out.

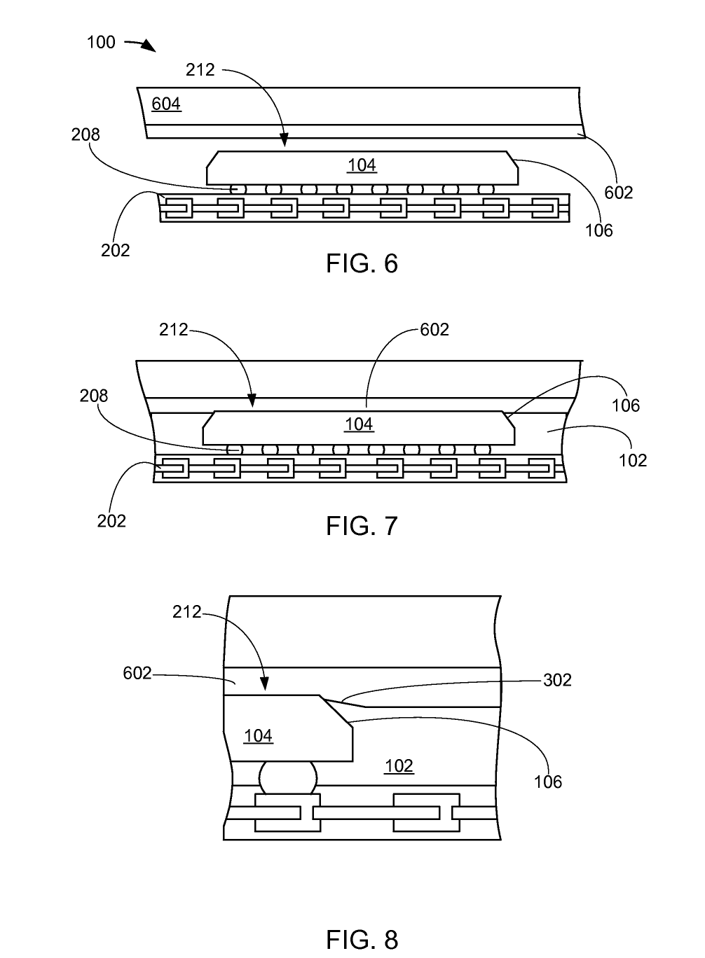

Referring now to FIG. 6, therein is shown a partial cross-sectional view of the integrated circuit packaging system 100 of FIG. 2 in a device-attachment phase of manufacture. The integrated circuit device 104 can be attached to the substrate 202 by the device interconnect 208.

A film 602 can be attached to a mold chase 604. The film 602 can include an adhesive tape, a laminated tape, an adhesive film, or a thermal release material. The film 602 can be pressed down on the integrated circuit device 104 by the mold chase 604. The film 602 can envelope the device top side 212 and partially cover the shaped side 106. The film 602 can contact the shaped side 106 and extend below the perimeter of the device top side 212.

Referring now to FIG. 7, therein is shown the structure of FIG. 6 in a film-assist molding phase. The integrated circuit device 104, the device interconnect 208, and the substrate 202 is encapsulated by the encapsulation 102. The film 602 extending below the perimeter of the device top side 212 and partially covering the shaped side 106 prevents mold flash and bleeding to the device top side 212.

The device top side 212 and the exposed portion 218 of FIG. 2 of the shaped side 106 protrude from the encapsulation 102 after the film 602 is removed. The extent of an overhang of the film 602 over a perimeter of the device top side 212 determines the shape and characteristics of the raised portion 302 of FIG. 3 of the encapsulation 102.

It has also been discovered that the raised portion 302 of the encapsulation 102 partially covering the shaped side 106 and below the device top side 212 provides a mold locking feature for the integrated circuit device 104 that prevents pull out of the integrated circuit device 104 from the encapsulation 102. The raised portion 302 partially covering the shaped side 106 increases adhesion strength because the shaped side 106 is embedded and anchored within the encapsulation 102.

It has also been discovered that present invention provides for the device top side 212 to be can exposed and above the encapsulation 102 because the shaped side 106 embedded in the encapsulation 102 prevents pull out.

Referring now to FIG. 8, therein is shown a detailed partial view of the structure of FIG. 7. The film 602 extends below the perimeter of the device top side 212 and below the exposed portion 218 of FIG. 2 on the periphery of the integrated circuit device 104.

The compression of the film 602 on the device top side 212 and the shaped side 106 provides a dam function to prevent mold bleeding onto the device top side 212. The compression of the film 602 on the device top side 212 and the shaped side 106 also determines the shape and characteristic of a surface of the raised portion 302 of the encapsulation 102.

It has been discovered that the shaped side 106 with the exposed portion 218 prevents mold bleed onto the device top side 212. For example, it has been unexpectedly found that the shaped side 106 functions as a dam to reduce the epoxy molding compound transfer velocity at the edges of the integrated circuit device 104. Reliability of the integrated circuit device 104 is increases because mold bleed is prevented from the device top side 212.

It has also been discovered that the present invention provides a consistent surface for mounting components on the device top side 212 because of the prevention of the mold bleed. The shaped side 106 prevents mold bleed onto the device top side 212 reducing manufacturing time and process steps because the mold bleed does not need subsequent removal.

It has also been discovered that the encapsulation 102 of FIG. 1 partially covering the shaped side 106 and below the device top side 212 provides a mold locking feature for the integrated circuit device 104 that prevents pull out of the integrated circuit device 104 from the encapsulation 102. The raised portion 302 of the encapsulation 102 partially covering the shaped side 106 increases adhesion strength because the shaped side 106 is embedded and anchored within the encapsulation 102.

It has also been discovered that present invention provides for the device top side 212 to be can exposed and above the encapsulation 102 because the shaped side 106 embedded in the encapsulation 102 prevents pull out.

It has also been discovered that the shaped side 106, the intersection of the shaped side 106 and the non-horizontal side 214 of FIG. 2, the non-horizontal side 214, and the intersection of the non-horizontal side 214 and the substrate 202 of FIG. 2 can be curved or rounded to provide increased surface area for a stronger mold lock. The curved or rounded surfaces provided increased area for mold to adhere thereon. A curved surface at the intersection of the non-horizontal side 214 and the substrate provides a mold lock between the encapsulation 102 and the integrated circuit device 104 to prevent pullout.

Further, it has been unexpectedly found that the shaped side 106 reduces stress during a singulation process of the integrated circuit device 104. The forming of the shaped side 106 facilitates singulation because less material must be cut through during singulation of a wafer to a die.

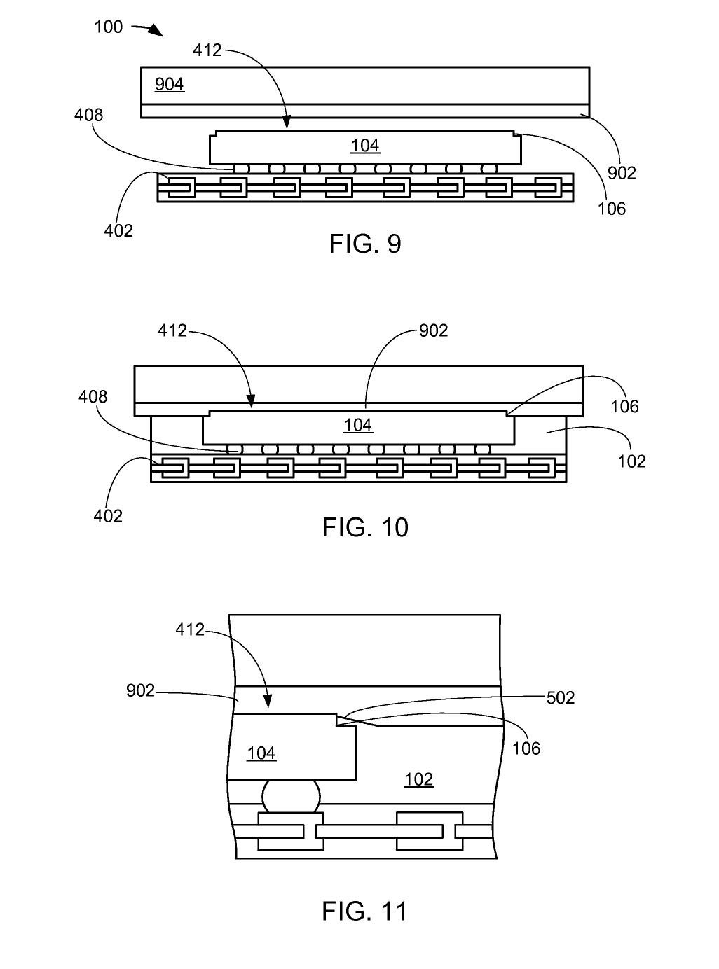

Referring now to FIG. 9, therein is shown a partial cross-sectional view of the integrated circuit packaging system 100 of FIG. 4 in a device-attachment phase of manufacture. The integrated circuit device 104 can be attached to the substrate 402 by the device interconnect 408.

A film 902 can be attached to a mold chase 904. The film 902 can include an adhesive tape, a laminated tape, an adhesive film, or a thermal release material. The film 902 can be pressed down on the integrated circuit device 104 by the mold chase 904. The film 902 can envelope the device top side 412 and partially cover the shaped side 106. The film 902 can contact the shaped side 106 and extend below the perimeter of the device top side 412.

Referring now to FIG. 10, therein is shown the structure of FIG. 9 in a film-assist molding phase. The integrated circuit device 104, the device interconnect 408, and the substrate 402 is encapsulated by the encapsulation 102. The film 902 extending below a perimeter of the device top side 412 and partially covering the shaped side 106 prevents mold flash and bleeding to the device top side 412.

The device top side 412 and the exposed portion 418 of FIG. 4 of the shaped side 106 protrude from the encapsulation 102 after the film 902 is removed. The extent of an overhang of the film 902 over the perimeter of the device top side 412 determines the shape and characteristics of the raised portion 502 of FIG. 5 of the encapsulation 102.

It has also been discovered that the raised portion 502 of the encapsulation 102 partially covering the shaped side 106 and below the device top side 412 provides a mold locking feature for the integrated circuit device 104 that prevents pull out of the integrated circuit device 104 from the encapsulation 102. The raised portion 502 partially covering the shaped side 106 increases adhesion strength because the shaped side 106 is embedded and anchored within the encapsulation 102.

It has also been discovered that present invention provides for the device top side 412 to be can exposed and above the encapsulation 102 because the shaped side 106 embedded in the encapsulation 102 prevents pull out.

Referring now to FIG. 11, therein is shown a detailed partial view of the structure of FIG. 7. The film 902 extends below the perimeter of the device top side 412 and below the exposed portion 418 of FIG. 4 on the periphery of the integrated circuit device 104.

The compression of the film 902 on the device top side 412 and the shaped side 106 provides a dam function to prevent mold bleeding onto the device top side 412. The compression of the film 902 on the device top side 412 and the shaped side 106 also determines the shape and characteristic of a surface of the raised portion 502 of the encapsulation 102.

It has been discovered that the shaped side 106 with the exposed portion 418 prevents mold bleed onto the device top side 412. For example, it has been unexpectedly found that the shaped side 106 functions as a dam to reduce the epoxy molding compound transfer velocity at the edges of the integrated circuit device 104. Reliability of the integrated circuit device 104 is increases because mold bleed is prevented from the device top side 412.

It has also been discovered that the present invention provides a consistent surface for mounting components on the device top side 412 because of the prevention of the mold bleed. The shaped side 106 prevents mold bleed onto the device top side 412 reducing manufacturing time and process steps because the mold bleed does not need subsequent removal.

It has also been discovered that the encapsulation 102 of FIG. 1 partially covering the shaped side 106 and below the device top side 412 provides a mold locking feature for the integrated circuit device 104 that prevents pull out of the integrated circuit device 104 from the encapsulation 102. The raised portion 502 of the encapsulation 102 partially covering the shaped side 106 increases adhesion strength because the shaped side 106 is embedded and anchored within the encapsulation 102.

It has also been discovered that present invention provides for the device top side 412 to be can exposed and above the encapsulation 102 because the shaped side 106 embedded in the encapsulation 102 prevents pull out.

It has also been discovered that the shaped side 106, the intersection of the shaped side 106 and the non-horizontal side 414 of FIG. 4, the non-horizontal side 414, and the intersection of the non-horizontal side 414 and the substrate 402 of FIG. 4 can be curved or rounded to provide increased surface area for a stronger mold lock. The curved or rounded surfaces provided increased area for mold to adhere thereon. A curved surface at the intersection of the non-horizontal side 414 and the substrate provides a mold lock between the encapsulation 102 and the integrated circuit device 104 to prevent pullout.

Further, it has been unexpectedly found that the shaped side 106 reduces stress during a singulation process of the integrated circuit device 104. The forming of the shaped side 106 facilitates singulation because less material must be cut through during singulation of a wafer to a die.

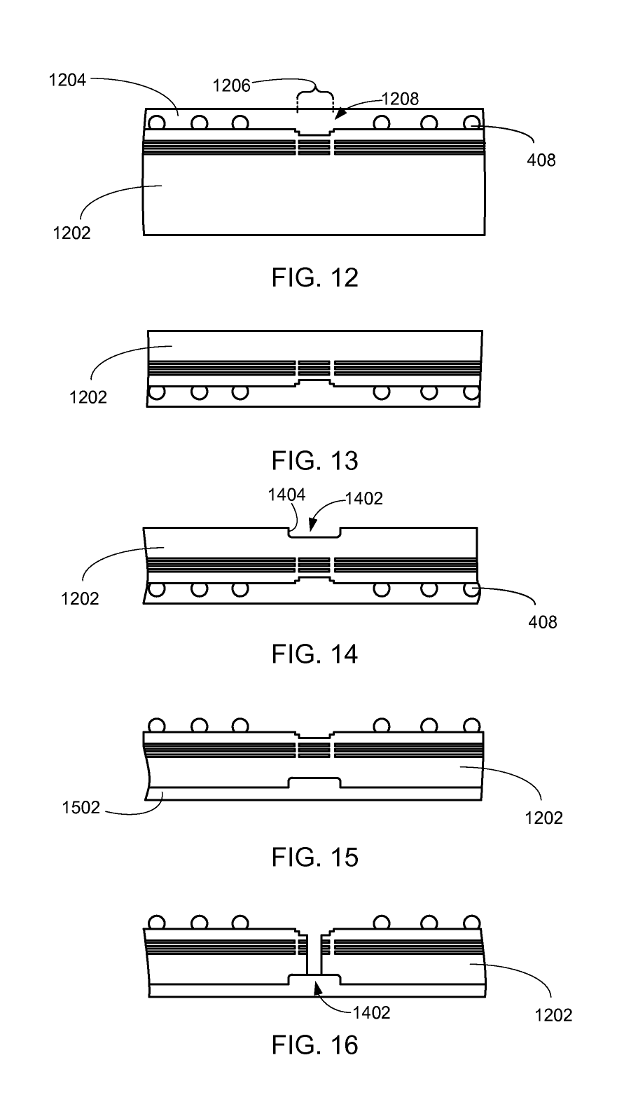

Referring now to FIG. 12, therein is shown a partial cross-sectional view of the integrated circuit packaging system of FIG. 4 in a wafer-mount phase of manufacture. A wafer 1202 can be provided with the device interconnect 408 attached to a side of the wafer 1202.

The device interconnect 408 and the wafer 1202 can be attached to an interconnect side tape 1204. The interconnect side tape 1204 can include an adhesive film, adhesive tape, or a laminated tape. The device interconnect 408 can be enveloped by the interconnect side tape 1204 for providing support in a destructible removal process such as back-grinding.

The wafer 1202 can include a saw street 1206 for a subsequent singulation process. The wafer 1202 can also include a pre-formed recess 1208 on a side of the wafer 1202 having the device interconnect 408. The pre-formed recess 1208 is formed with a destructible removal process including back-grinding, mechanical cutting, sawing, or laser ablation. The saw street 1206 can include the pre-formed recess 1208. The pre-formed recess 1208 can include a sidewall with an orthogonal side to form a step profile or a multiple step profile.

Referring now to FIG. 13, therein is shown the structure of FIG. 12 in a destructible removal process phase of manufacture. The wafer 1202 can be shaved or grinded to reduce the profile of the wafer 1202. The destructible removal process can include back-grinded, cutting, or sawing.

Referring now to FIG. 14, therein is shown the structure of FIG. 13 in a cutting phase of manufacture. A recess 1402 can be formed on a side of the wafer 1202 opposite to the side of the wafer 1202 attached to the device interconnect 408. The recess 1402 can be formed using a destructible removal process such as mechanical cutting, sawing, grinding, or laser ablation.

The recess 1402 can include a sidewall 1404. The size and shape of the recess 1402 can be determined by the specifications of the shaped side 106 of FIG. 4. For example, the sidewall 1404 of the recess 1402 can have orthogonal sides to form a step profile of the shaped side 106 of FIG. 4.

Further for example, the sidewall 1404 can include a sloped straight profile or a profile having a curved sectioned surface, an angled flat sectioned surface, or a surface formed having any combination of surfaces thereof. For example, a destructible removal process such as mechanical cutting, sawing, grinding, or laser ablation can be used to form the sidewall 1404 having a straight sloped profile as seen in FIG. 1.

Referring now to FIG. 15 therein is shown the structure of FIG. 14 in a tape-removal phase. The interconnect side tape 1204 of FIG. 12 is removed and a top-side tape 1502 can be placed on the side of the wafer 1202 having the recess 1402 of FIG. 14.

Referring now to FIG. 16 therein is shown the structure of FIG. 15 in a singulation phase. The wafer 1202 is singulated at a midpoint of the recess 1402. The singulation of the wafer 1202 can use a destructible removal process such as mechanical cutting, sawing, or laser ablation. The singulation process forms the non-horizontal side 414 of FIG. 4.

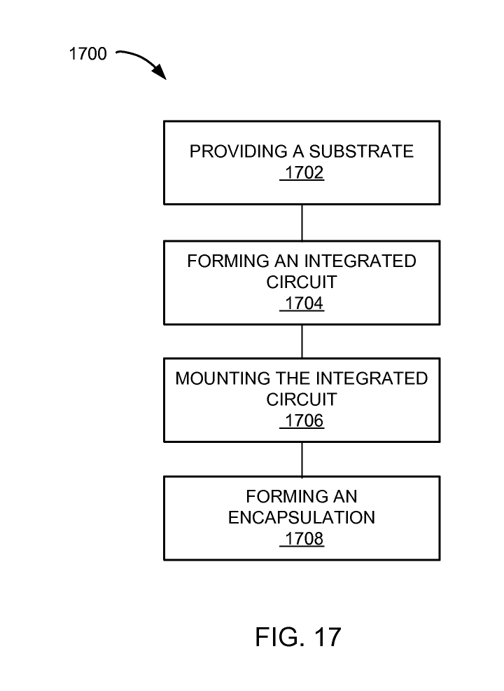

Referring now to FIG. 17, therein is shown a flow chart of a method 1700 of manufacture of the integrated circuit packaging system in a further embodiment of the present invention. The method 1700 includes: providing a substrate in a block 1702; forming an integrated circuit device having a shaped side in a block 1704; mounting the integrated circuit device on the substrate in a block 1706; forming an encapsulation on the substrate and the integrate circuit device with the shaped side partially exposed from the encapsulation in a block 1708.

Thus, it has been discovered that the integrated circuit packaging system of the present invention furnishes important and heretofore unknown and unavailable solutions, capabilities, and functional aspects for mold interlock. The resulting method, process, apparatus, device, product, and/or system is straightforward, cost-effective, uncomplicated, highly versatile and effective, can be surprisingly and non-obviously implemented by adapting known technologies, and are thus readily suited for efficiently and economically manufacturing integrated circuit packaging systems fully compatible with conventional manufacturing methods or processes and technologies.

Another important aspect of the present invention is that it valuably supports and services the historical trend of reducing costs, simplifying systems, and increasing performance. These and other valuable aspects of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

1. A method of manufacture of an integrated circuit packaging system comprising:
providing a substrate;
forming an integrated circuit device having a shaped side;
mounting the integrated circuit device on the substrate; and
forming an encapsulation on the substrate and the integrate circuit device with the shaped side partially exposed from the encapsulation, the encapsulation having a raised portion, the raised portion includes a sloped profile characteristic of being formed by a film assist molding process.

2. The method as claimed in claim 1 wherein forming the encapsulation includes forming the encapsulation with a device top side of the integrated circuit device above the encapsulation.

3. The method as claimed in claim 1 wherein forming the encapsulation include forming the raised portion of the encapsulation partially covering the shaped side.

4. The method as claimed in claim 1 wherein forming the encapsulation includes forming an exposed portion of the shaped side above the encapsulation.

5. The method as claimed in claim 1 wherein mounting the integrated circuit device includes attaching the integrated circuit device to the substrate by a device interconnect.

6. A method of manufacture of an integrated circuit packaging system comprising:
providing a substrate;
forming an integrated circuit device having a shaped side;
mounting the integrated circuit device on the substrate;
pressing a film on the integrated circuit device and the shaped side;
forming an encapsulation on the substrate and the integrate circuit device, the encapsulation having a raised portion, the raised portion includes a sloped profile characteristic of being formed by the film; and
removing the film for partially exposing the shaped side from the encapsulation.

7. The method as claimed in claim 6 wherein forming the encapsulation includes forming the raised portion of the encapsulation having a surface characteristic of being formed by compression of the film on the shaped side.

8. The method as claimed in claim 6 wherein forming the shaped side includes forming a surface of the shaped side having characteristic of a destructible removal process.

9. The method as claimed in claim 6 wherein forming the encapsulation includes forming the raised portion of the encapsulation between a device top side and an encapsulation top side.

10. The method as claimed in claim 6 wherein forming the shaped side includes forming a non-horizontal side of the integrated circuit device having a surface characteristic of a destructible removal process.

11. An integrated circuit packaging system comprising:
a substrate;
an integrated circuit device mounted on the substrate, the integrated circuit device includes a shaped side; and
an encapsulation formed on the substrate and the integrate circuit device with the shaped surface partially exposed from the encapsulation, the encapsulation having a raised portion, the raised portion includes a sloped profile characteristic of being formed by a film assist molding process.

12. The system as claimed in claim 11 wherein the integrated circuit device includes a device top side of the integrated circuit device above the encapsulation.

13. The system as claimed in claim 11 wherein the encapsulation includes the raised portion partially covering the shaped side.

14. The system as claimed in claim 11 wherein the integrated circuit device includes an exposed portion of the shaped side above the encapsulation.

15. The system as claimed in claim 11 wherein the integrated circuit device mounted on the substrate includes a device interconnect.

16. The system as claimed in claim 11 wherein the shaped side includes an exposed portion between a device top side and an encapsulation top side.

17. The system as claimed in claim 16 wherein the encapsulation includes the raised portion having a surface characteristic of being formed by compression of a film on the shaped side.

18. The system as claimed in claim 16 wherein the shaped side includes a surface of the shaped side having characteristic of a destructible removal process.

19. The system as claimed in claim 16 wherein the encapsulation includes the raised portion between a device top side and an encapsulation top side.

20. The system as claimed in claim 16 wherein of the integrated circuit device includes a non-horizontal side having a surface characteristic of a destructible removal process.
